(19) United States
(12) Patent Application Publication
(10) Pub. No.: US 2025/0314604 A1
(43) Pub. Date: Oct. 9, 2025

(54) DEVICE FOR THERMOAMPEROMETRY AND THERMOCOULOMETRY, AND ANALYSIS METHOD USING SAME

(71) Applicants: EWHA UNIVERSITY-INDUSTRY COLLABORATION FOUNDATION, Seoul (KR); KOREA RESEARCH INSTITUTE OF CHEMICAL TECHNOLOGY, Daejeon (KR)

(72) Inventors: Byung-Kwon KIM, Seoul (KR); Sua SONG, Seoul (KR); Jin Hee LEE, Daejeon (KR)

(21) Appl. No.: 19/188,058

(22) Filed: Apr. 24, 2025

Related U.S. Application Data
(63) Continuation of application No. PCT/KR2023/016868, filed on Oct. 27, 2023.

(30) Foreign Application Priority Data
Oct. 28, 2022 (KR) 10-2022-0140898
Jul. 24, 2023 (KR) 10-2023-0096347

(51) Int. Cl. G01N 25/02; G01N 27/04; G01N 27/26; G01R 19/00; G01R 29/24

(52) U.S. Cl. CPC G01N 25/02; G01N 27/04; G01N 27/26; G01R 19/0092; G01R 29/24

(57) ABSTRACT

A device for thermoamperometry and thermocoulometry and an analysis method are provided. One aspect of the present invention provides a device for thermoamperometry and thermocoulometry, including: a chamber filled with a measurement solution containing a target material and an electrolyte; an electrode unit immersed in the measurement solution; a temperature controller adjusting a temperature of the measurement solution; a temperature measurement unit immersed in the measurement solution and spaced apart from the electrode unit; and a controller connected to both the temperature measurement unit and the electrode unit.

### CROSS-REFERENCE TO RELATED APPLICATIONS

This application is a continuation of PCT Application No. PCT/KR2023/016868, filed on Oct. 27, 2023, which claims priority to Korean Patent Application Numbers 10-2022-0140898, filed on Oct. 28, 2022, and 10-2023-0096347, filed on Jul. 24, 2023, all of which are hereby incorporated by reference in their entirety.

### TECHNICAL FIELD

The present disclosure relates to a device for thermoamperometry and thermocoulometry, and more particularly, to a device for thermoamperometry and thermocoulometry and an analysis method using the same.

### BACKGROUND

Polymers that undergo various physical or chemical changes due to external stimuli are referred to as stimuli-responsive polymers. The stimuli-responsive polymers can respond to small changes in environmental parameters such as temperature, light, pH, magnetic field, and ionic strength.

In particular, thermoresponsive polymers that respond to temperature changes have the advantage of being able to easily control the intensity of stimulation and thus have been widely applied in pharmaceutical or bio fields. The thermoresponsive polymers can be divided into upper critical solution temperature (UCST) polymers and lower critical solution temperature (LCST) polymers. Among these, extensive research has been conducted on the synthesis of LCST polymers.

Meanwhile, the cloud point temperature T_{cp} has been used to analyze the phase transition behavior of thermoresponsive polymers. Conventional analysis methods, such as NMR, DLS, and UV-vis spectroscopy, have been employed to analyze the cloud point temperature. However, these methods have problems such as slow analysis speeds and difficulties in accurately determining the phase transition temperature, and are limited in that they only provide information on the physicochemical properties of polymer aggregates formed above the phase transition point.

### DISCLOSURE OF THE INVENTION

### Problems to be Solved by the Invention

The present disclosure is conceived to provide a device for thermoamperometry and thermocoulometry, capable of measuring a current or charge of various target materials by an electrochemical method.

Also, the present disclosure is conceived to provide an analysis method capable of outputting current or charge data depending on a temperature of a measurement solution.

The objects of the present disclosure are not limited to those described above, and other objects and advantages of the present disclosure may be understood by the following description and will be apparent from the embodiments of the present disclosure. Further, it will be readily understood that the objects and advantages of the present disclosure may be realized by the means set forth in the appended claims and their combination.

### Means for Solving the Problems

According to a first aspect of the present disclosure, there is provided a device for thermoamperometry and thermocoulometry, including: a chamber filled with a measurement solution containing a target material and an electrolyte; an electrode unit immersed in the measurement solution; a temperature controller adjusting a temperature of the measurement solution; a temperature measurement unit immersed in the measurement solution and spaced apart from the electrode unit; and a controller connected to both the temperature measurement unit and the electrode unit.

According to a second aspect of the present disclosure, the target material according to the first aspect may include at least one selected from a conductive material and a non-conductive material.

According to a third aspect of the present disclosure, the target material according to the second aspect may include a non-conductive material and the measurement solution may further include a redox species.

According to a fourth aspect of the present disclosure, the target material according to any one of the first to third aspects may include a thermoresponsive polymer.

According to a fifth aspect of the present disclosure, the thermoresponsive polymer according to the fourth aspect may include a lower critical solution temperature (LCST) polymer.

According to a sixth aspect of the present disclosure, the electrode unit according to any one of the first to fifth aspects may include a working electrode and a reference electrode spaced apart from each other.

According to a seventh aspect of the present disclosure, the electrode unit according to the sixth aspect may further include a counter electrode.

According to an eighth aspect of the present disclosure, the device according to any one of the first to seventh aspects may further include an output unit connected to the controller.

According to a ninth aspect of the present disclosure, there is provided an analysis method using the device for thermoamperometry and thermocoulometry according to any one of the first to eighth aspects, the method including: a process of outputting a first data regarding a temperature of the measurement solution over time; a process of outputting a second data regarding a current or charge of the measurement solution over time; and a process of outputting a third data regarding the current or charge of the measurement solution depending on the temperature of the measurement solution, based on the first and second data.

The above-described aspects of the present disclosure do not include all aspects or features of the present disclosure. Other aspects or features, and effects of the present disclosure will be clearly understood from the following descriptions of embodiments.

### EFFECTS OF THE INVENTION

According to an aspect of the present disclosure, it is possible to provide a device for thermoamperometry and thermocoulometry, capable of measuring a current or charge of various target materials by an electrochemical method.

According to another aspect of the present disclosure, it is possible to provide an analysis method capable of outputting current or charge data depending on a temperature of a measurement solution.

The above and other effects of the present disclosure will be described below together with examples for carrying out the present disclosure.

### BRIEF DESCRIPTION OF THE DRAWINGS

FIG. 1 is a schematic diagram illustrating a device for thermoamperometry and thermocoulometry according to an example of the present disclosure.

FIG. 2A shows the current-temperature (i-T) graph obtained during heating of the measurement solution containing the electrolyte, anthracene, and PES₁₀ from 25° C. to 70° C., and

FIG. 2B is a schematic diagram dividing current changes on the surface of the working electrode into three stages.

FIG. 3A shows a Nyquist plots depending on temperature, and FIG. 3B shows a graph of current and real impedance component Z′ depending on temperature.

FIG. 4A(i) to FIG. 4A(iii) are graphs of current-temperature (i-T) at different concentrations of the electrolyte (Nbu₄TfO) of 25 mM (i), 50 mM (ii), and 100 mM (iii) when the concentration of the thermoresponsive polymer (PES₁₀) is 1.5 mg/mL.

FIG. 4B(i) to FIG. 4B(iii) are graphs of current-temperature (i-T) at different concentrations of the electrolyte (Nbu₄TfO) of 25 mM (i), 50 mM (ii), and 100 mM (iii) when the concentration of the thermoresponsive polymer (PES₁₀) is 2.5 mg/mL.

FIG. 4C(i) to FIG. 4C(iii) are graphs of current-temperature (i-T) at different concentrations of the electrolyte (Nbu₄TfO) of 25 mM (i), 50 mM (ii), and 100 mM (iii) when the concentration of the thermoresponsive polymer (PES₁₀) is 4.0 mg/mL.

FIG. 5A is a graph of the electrochemical cloud point temperature T_{ecp} depending on the concentration of the electrolyte derived by using the device for thermoamperometry and thermocoulometry according to the present disclosure, and FIG. 5B is a graph of the cloud point temperature T_{cp} depending on the concentration of the electrolyte derived by using a UV-Vis spectrometer.

FIG. 6A is a graph of a current (nA) of a measurement solution depending on a time(s) which is output by using the device for thermoamperometry and thermocoulometry according to the present disclosure.

FIG. 6B is a graph of a temperature (° C.) of the measurement solution depending on the time(s) which is output by using the device for thermoamperometry and thermocoulometry according to the present disclosure.

FIG. 6C is a graph of the current (nA) of the measurement solution depending on the temperature (° C.) of the measurement solution which is output by using the device for thermoamperometry and thermocoulometry according to the present disclosure.

### BEST MODE FOR CARRYING OUT THE INVENTION

The terms of a singular form may include plural forms unless otherwise specified.

The numerical ranges expressed using the term “to” herein refer to the numerical ranges including the values specified ahead or behind the term as lower limit values and upper limit values, respectively. When a plurality of numerical values are mentioned for an upper limit or a lower limit of any numerical range, the range disclosed herein can be understood as a range having any one of the mentioned plurality of upper limit values as an upper limit value thereof and any one of the plurality of lower limit values as a lower limit value thereof.

Throughout the whole document, the term “connected to (contacted with or coupled to)” may be used to designate a connection or coupling of one element to another element and includes both an element being “directly connected to (contacted with or coupled to)” another element and an element being “indirectly connected to (contacted with or coupled to)” another element via another element.

Throughout the whole document, the term “conductive material” may be defined as a material having a conductivity of 10⁶ S/m or more, and the term “non-conductive material” may be defined as a material having a conductivity of less than 10⁶ S/m.

### 1. Device for Thermoamperometry and Thermocoulometry

According to an aspect of the present disclosure, there is provided a device for thermoamperometry and thermocoulometry, including: a chamber filled with a measurement solution containing a target material and an electrolyte; an electrode unit immersed in the measurement solution; a temperature controller adjusting a temperature of the measurement solution; a temperature measurement unit immersed in the measurement solution and spaced apart from the electrode unit; and a controller connected to both the temperature measurement unit and the electrode unit. According to an aspect of the present disclosure, the temperature controller configured to adjust a temperature of the measurement solution is combined with the electrode unit. Thus, is it possible to output current or charge data depending on the temperature of the measurement solution.

Hereinafter, the configuration of the present disclosure will be described in detail with reference to the accompanying drawings.

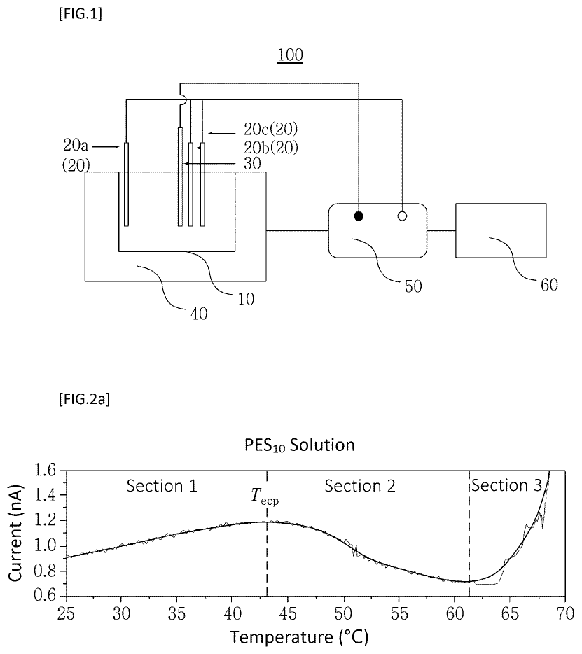

FIG. 1 is a schematic diagram illustrating a device for thermoamperometry and thermocoulometry according to an example of the present disclosure.

Referring to FIG. 1, a device 100 for thermoamperometry and thermocoulometry according to the present disclosure may include a chamber 10, an electrode unit 20, a temperature measurement unit 30, a temperature controller 40, a controller 50, and an output unit 60.

The chamber 10 according to the present disclosure is a member in which a measurement solution is filled. More specifically, the chamber 10 may be filled with a measurement solution containing a target material and an electrolyte. The target material is an object of current or charge measurement.

The target material according to the present disclosure is not particularly limited, but may include various materials that can serve as an object of current or charge measurement. For example, the target material may include at least one selected from a conductive material and a non-conductive material. More specifically, the target material may include ions, metals, polymers, and small molecules. For example, the polymers may include at least one selected from conductive polymers and non-conductive polymers.

According to an example of the present disclosure, the target material may include a non-conductive material and the measurement solution may further include a redox species. The non-conductive material itself is not electrically conductive, and since the measurement solution further includes a redox species, it is possible to induce an electrochemical reaction in which electrons are transferred on the surface of an electrode. Accordingly, a current or charge of the non-conductive material can be measured indirectly. More specifically, the redox species is not particularly limited, but may be appropriately selected depending on the type of target material.

For example, the redox species may include at least one selected from anthracene, benzanthracene, 9,10-Diphenylanthracene, ferrocyanide ion, ferricyanide ion, hexa-amine ruthenium(III) ion, hydronquinone, ascorbic acid, dopamine, ferrocenemethanol, ferrocene, ferrocenedimethanol, alpha-Methylferrocenemethanol, ferrocene carboxylic acid, ferrocene dicarboxylic acid, ferrocene aldehyde, and derivates thereof.

According to some examples of the present disclosure, when the target material is a thermoresponsive polymer, a cloud point temperature T_{ecp} analyzed by an electrochemical method may decrease as a concentration of the thermoresponsive polymer increases under the same electrolyte concentration conditions.

For example, the thermoresponsive polymer may include one selected from the group consisting of poly(arylene ether sulfone), poly(N-isopropylacrylamide), poly(N,N-diethylacrylamide), poly(N-ethylmethacrylamide), poly(methyl vinyl ether), poly(2-ethoxyethyl vinyl ether), poly(N-vinylcaprolactam), poly(N-vinylisobutyramide), and poly(N-vinyl-n-butyramide); or a copolymer or mixture containing two or more thereof.

According to another example of the present disclosure, the target material may include a thermoresponsive polymer. In this case, the measurement solution may further include the redox species to facilitate electron transfer. Herein, the thermoresponsive polymer refers to a material that responds to temperature changes and may include a lower critical solution temperature (LCST)-type polymer.

The electrode unit 20 according to the present disclosure may induce an electrochemical reaction to directly or indirectly measure a current or charge of the target material. More specifically, the electrode unit 20 may be immersed in the measurement solution.

According to an example of the present disclosure, the electrode unit 20 may include a working electrode 20c and a reference electrode 20b spaced apart from each other.

The working electrode 20c according to the present disclosure may induce an electrochemical reaction to allow a current to flow. For example, although not particularly limited, the working electrode 20c may include a carbon-based electrode. More specifically, the working electrode 20c may be a carbon ultramicroelectrode (C-UME) or a glassy carbon electrode (GCE).

The reference electrode 20b according to the present disclosure may be used in combination with the working electrode to form a battery circuit for measuring a potential of the working electrode where the electrochemical reaction occurs. For example, although not particularly limited, the reference electrode 20b may include a silver wire (Ag wire).

According to another example of the present disclosure, the electrode unit 20 may further include a counter electrode 20a. More specifically, the counter electrode 20a may be spaced apart from the reference electrode 20b and the working electrode 20c.

The counter electrode 20a according to the present disclosure may form an electric circuit to enable charge transfer in an electrochemical cell. For example, although not particularly limited, the counter electrode 20a may include a platinum wire (Pt wire).

The electrolyte according to the present disclosure may be contained in the measurement solution to promote electron transfer on the surface of the electrode. For example, although not particularly limited, the electrolyte may be appropriately selected depending on the type of target material.

For example, the electrolyte may include one or more selected from the group consisting of tetrabutylammonium trifluoromethanesulfonate, tetrabutylammonium perchlorate, tetrabutylammonium hexafluorophosphate, tetrabutylammonium tetrafluoroborate, ionic liquid, NaCl, KCl, phosphate ion, and tris(hydroxymethyl)aminomethane.

According to some examples of the present disclosure, when the target material is a thermoresponsive polymer, the cloud point temperature T_{ecp} analyzed by the electrochemical method may increase as a concentration of the electrolyte increases under the same thermoresponsive polymer concentration conditions. More specifically, as the concentration of the electrolyte increases, aggregation of LCST-type thermoresponsive polymers can be effectively suppressed. Thus, it is possible to increase an electrochemical cloud point temperature at which aggregation of polymers begins.

The temperature controller 40 according to the present disclosure may control a temperature of the measurement solution filled in the chamber 10. For example, although not particularly limited, the method of controlling the temperature of the measurement solution by the temperature controller 40 may be implemented in various ways. More specifically, the temperature controller 40 may be a hotplate stirrer for heating and stirring the measurement solution, a heater for controlling the temperature of the measurement solution, or an electrical device for controlling the temperature of the measurement solution by using electric wires. According to an example of the present disclosure, the temperature controller 40 may be disposed under the chamber to control the temperature of the measurement solution within the chamber.

More specifically, the temperature controller 40 may output current or charge data depending on the temperature of the measurement solution through the output unit 60, which will be described below, by controlling the temperature of the measurement solution. Conventionally, a current or charge is individually plotted for each specific temperature point to obtain current or charge data of a measurement solution, which results in excessive time and cost consumption. According to an aspect of the present disclosure, the temperature controller 40 controls the temperature of the measurement solution to output a third data regarding the current or charge of the measurement solution depending on (continuous) temperature changes of the measurement solution by aggregating a first data regarding the temperature of the measurement solution over time and a second data regarding the current or charge of the measurement solution over time. As a result, it is possible to easily resolve the conventional problems of excessive time and cost consumption.

The temperature measurement unit 30 according to the present disclosure may measure the temperature of the measurement solution controlled by the temperature controller 40. More specifically, the temperature measurement unit 30 may be immersed in the measurement solution and spaced apart from the electrode unit 20.

For example, although not particularly limited, the temperature measurement unit 30 may be any device capable of measuring the temperature of the measurement solution. More specifically, the temperature measurement unit 30 may be a temperature sensor device.

The controller 50 according to the present disclosure may apply a voltage to the electrode unit 20 and control the temperature controller 40 to regulate the temperature of the measurement solution. More specifically, the controller 50 may be connected to the temperature measurement unit 30 and the electrode unit 20. Herein, the controller 50 is connected to the temperature measurement unit 30, and, thus, data regarding the temperature of the measurement solution over time, which is controlled by the temperature controller 40, can be transmitted to the controller 50. Further, the controller 50 is connected to the electrode unit 20, and, thus, data regarding the current or charge of the measurement solution over time can be transmitted to the controller 50.

The controller 50 according to the present disclosure may include a potentiostat configured to apply a voltage to the electrode unit 20. More specifically, the potentiostat may be connected to the electrode unit 20. For example, the potentiostat may be a commercially available potentiostat, and specifically a potentiostat equipped with the electrode unit 20.

The output unit 60 according to the present disclosure may output a third data regarding the current or charge of the measurement solution depending on continuous temperature changes of the measurement solution, based on a first data regarding the temperature of the measurement solution over time and a second data regarding the current or charge of the measurement solution over time which have been transmitted to the controller 50. According to an aspect of the present disclosure, by outputting the third data, it is possible to easily resolve the conventional need to plot and measure the current or charge of the measurement solution for each specific temperature.

More specifically, the output unit 60 may be connected to the controller 50. The output unit 60 may aggregate the first and second data received through the controller 50 and output the third data.

For example, at least one of the controller 50 and the output unit 60 may be a hardware device capable of executing CHI and Pasco Capstone software.

### 2. Analysis Method

According to another aspect of the present disclosure, there is provided an analysis method using the device for thermoamperometry and thermocoulometry according to some examples, the method including: a process of outputting a first data regarding a temperature of the measurement solution over time; a process of outputting a second data regarding a current or charge of the measurement solution over time; and a process of outputting a third data regarding the current or charge of the measurement solution depending on the temperature of the measurement solution, based on the first and second data.

In some examples, the process of outputting the first data and the process of outputting the second data may be performed independently and simultaneously. According to some examples of the present disclosure, when the target material is a thermoresponsive polymer, the phase transition behavior of the thermoresponsive polymer can be easily analyzed by the analysis method of the present disclosure. For example, the cloud point temperature at which the measurement solution begins to appear cloudy can be newly derived by the electrochemical method. More specifically, a temperature at which aggregation of polymers begins can be newly derived as the electrochemical cloud point temperature by analyzing the third data regarding the current or charge depending on the temperature of the measurement solution.

Conventionally, a current or charge is individually plotted for each specific temperature point to obtain current or charge data of a measurement solution, which results in excessive consumption of analysis time and cost. Accordingly, it is difficult to analyze the current or charge of the measurement solution in response to continuous temperature changes of the measurement solution. According to an aspect of the present disclosure, by combining the process of outputting the first data regarding the temperature of the measurement solution over time, the process of outputting the second data regarding the current or charge of the measurement solution over time; and the process of outputting the third data regarding the current or charge of the measurement solution depending on the temperature of the measurement solution by aggregating the first and second data, it is possible to easily observe changes in current or charge depending on (continuous) temperature changes of the measurement solution. As a result, it is possible to derive a new type of temperature-current or temperature-charge graph.

As described above with reference to FIG. 1, the output unit 60 may be used as a means for aggregating the first and second data. The output unit 60 may output the third data regarding the current or charge of the measurement solution depending on the temperature of the measurement solution by aggregating the first data regarding the temperature of the measurement solution over time and the second data regarding the current or charge of the measurement solution over time which have been transmitted to the controller 50. Herein, the temperature of the measurement solution may refer to a continuous range of temperatures.

### MODE FOR CARRYING OUT THE INVENTION

Hereinafter, examples of the present disclosure will be described in detail so that a person with ordinary skill in the art can easily accomplish the present disclosure, but they are only examples and the range of the present disclosure is not limited thereto.

### Example 1: Fabrication of Device for Thermoamperometry and Thermocoulometry

As shown in FIG. 1, the device 100 for thermoamperometry and thermocoulometry according to the present disclosure may include the chamber 10, the electrode unit 20, the temperature controller 40, the temperature measurement unit 30, the controller 50 equipped with the potentiostat, and the output unit 60. More specifically, electrochemical analysis tests were performed by using potentiostats (CHI617B and CHI760E) from CH Instruments Inc., equipped with a three-electrode cell system.

The electrode unit is composed of a working electrode equipped with: either a carbon ultramicroelectrode (C-UME) with a diameter of 10 um or a glassy carbon electrode (GCE) with a diameter of 3 mm; a reference electrode made of an Ag wire with a diameter of 0.5 mm; and a counter electrode made of a Pt wire with a diameter of 0.8 mm.

Ferrocene (0.1 mM) was added to each electrochemical measurement set as an internal standard to calibrate the potential range.

A temperature of the measurement solution filled in the chamber was controlled by using a digital hotplate stirrer (PC-420D available from Corning Inc.), which served as the temperature controller 40, and the temperature was recorded by a temperature sensor (PS-2125 available from PASCO Scientific Inc.).

All the tests were performed by using a beaker-type cell with a volume of 16 mL. The cell equipped with three electrodes and a temperature sensor was placed and heated in the chamber (water bath) on the digital hotplate stirrer. Temperature, current, and time data were converted by using CHI and Pasco Capstone software.

### Example 2: Analysis of Phase Transition Behavior of LCST Polymer

The electrochemical measurement system was designed to monitor the phase transition behavior of LCST-type polymers in an organic solution in real time as the temperature of the measurement solution increased. Measurement solutions were prepared containing different concentrations of the electrolyte (tetrabutylammonium trifluoromethanesulfonate) (hereinafter, referred to as “NBu₄TfO”), poly(arylene ether sulfone) with a degree of polymerization of 10 (hereinafter, referred to as “PES₁₀”), 0.1 mM anthracene (Ant), and 1,2-dimethoxyethane (DME).

Herein, anthracene was selected as the redox species to ensure thermal stability in the organic solution. The electrode unit was arranged in the electrochemical cell to measure an anodic current of anthracene. The temperature measurement unit was placed within the cell to simultaneously obtain temperatures and current signals while the measurement solution was heated. As the cell was heated, a current-time (i-t) response was obtained from amperometric curves and a temperature-time (T-t) response was simultaneously recorded by the temperature measurement unit.

A current-temperature (i-T) graph was derived based on the current-time (i-t) and temperature-time (T-t) responses.

### Example 2.1: Real-Time Electrochemical Analysis of Phase Transition in LCST-Type Polymer

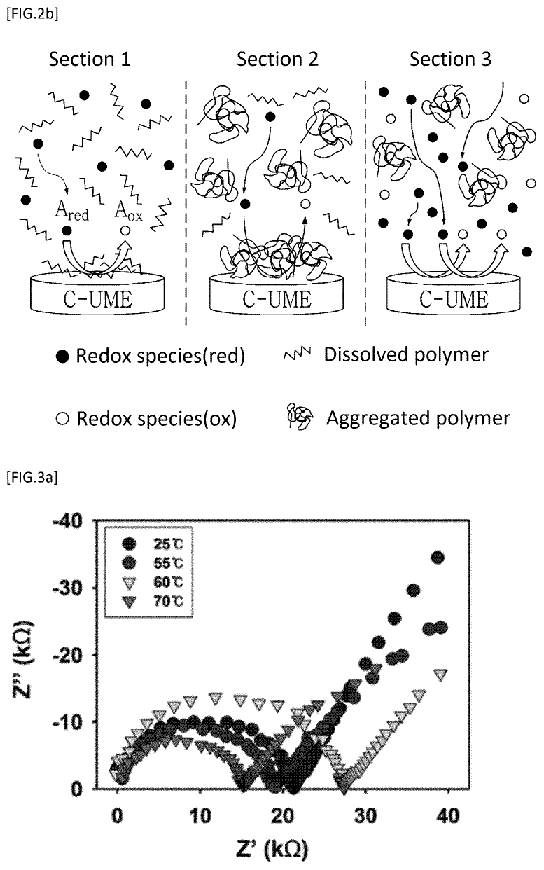

FIG. 2A shows the current-temperature (i-T) graph obtained during heating of the measurement solution containing the electrolyte, anthracene, and PES₁₀ from 25° C. to 70° C., and FIG. 2B is a schematic diagram dividing current changes on the surface of the working electrode into three stages. More specifically, the measurement solution contained PES₁₀, the electrolyte (25 mM Nbu₄TfO), the solvent (DME), and anthracene (0.1 mM).

Referring to FIG. 2A, it can be seen that for the measurement solution containing the thermoresponsive polymer (PES₁₀) unlike a measurement solution containing a non-thermoresponsive polymer (e.g., polystyrene) in which a current increases linearly with increasing temperature, the current-temperature (i-T) graph exhibits three distinct stages. This behavior of the graph is presumed to result from a difference in phase transition of the thermoresponsive polymer.

A steady state current iₛₛ at the working electrode can be affected by the diffusion coefficient of anthracene, which is affected by two factors including the temperature and the dynamic viscosity of the measurement solution. Therefore, by adjusting the diffusion coefficient of anthracene, data regarding the steady state current depending on temperature changes was obtained.

Referring to FIG. 2A and FIG. 2B, as the temperature of the measurement solution increases, the viscosity of the measurement solution decreases and the steady state current increases. However, as for the measurement solution containing the thermoresponsive polymer, the steady state current increased as the temperature of the measurement solution increased in a range of 25° C. to 43.1° C. (first range), the steady state current continuously decreased in a range of 43.1° C. to 62.1° C. (second range), and the steady state current increased as the temperature of the measurement solution increased at greater than 62.1° C. (third range). More specifically, in the range of 43.1° C. to 62.1° C. (second range), thermoresponsive polymer aggregates were formed on the surface of the electrode. Thus, it can be presumed that the current decreased due to an increase in charge-transfer resistance R_{ct}.

As shown in FIG. 2B, in the first range, the current increased linearly as the temperature of the measurement solution increased. It can be presumed that although a sufficient amount of the thermoresponsive polymer was present in the measurement solution, the temperature was not yet high enough to form polymer aggregates.

In the second range, the thermoresponsive polymer was aggregated at 43.1° C. on the surface of the electrode, and, thus, the actual electrode area was reduced and the measured current started to decrease.

In the third range, as the temperature of the measurement solution increased due to an increase in diffusion coefficient of redox species and the increase in actual electrode area, the current increased rapidly. In the third range, additional factors did not affect current changes, and the saturated polymer aggregates were separated from the electrode. Also, as the temperature of the measurement solution approached the boiling point of the solvent, convection effects increased and the current increased sharply.

The test results show that the highest temperature point observed in the first and second ranges of the current-time (i-T) graph is newly derived as the electrochemical cloud point temperature T_{ecp} of the thermoresponsive polymer.

### Example 2.2: EIS Analysis for Charge-Transfer Resistance Measurement at Electrode Surface

An electrochemical impedance spectroscopy (EIS) analysis was performed to measure a charge-transfer resistance on the surface of the electrode. More specifically, a potentiostat CHI760E equipped with three electrodes (GCE, Ag wire, and Pt wire) was used for the EIS analysis. An electrode impedance and a temperature of a measurement solution containing 2.5 mg/mL PES₁₀, 0.1mM anthracene (Ant), the electrolyte (50 mM NBu₄TfO), and the solvent (DME) were measured simultaneously from the measurement solution. The measurement solution in the chamber was stirred and heated from 25° C. to 70° C., and an electrochemical impedance was measurement at an AC frequency range of 1 to 1×10⁶ Hz with a potential amplitude of 5 mV. The charge-transfer resistance R_{ct} was obtained at an applied potential of +0.8 V (vs Fc/Fc⁺), corresponding to an oxidation potential of anthracene (Ant).

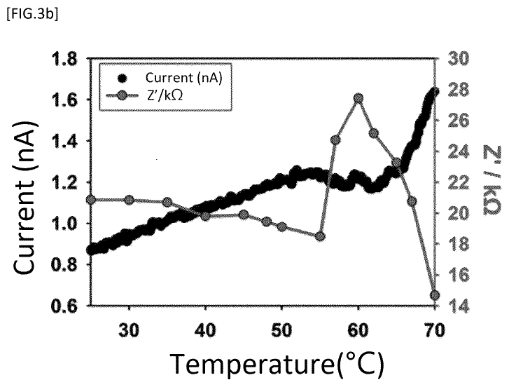

FIG. 3A shows a Nyquist plots depending on temperature, and FIG. 3B shows a graph of current and real impedance component Z′ depending on temperature.

Referring to FIG. 3A and FIG. 3B, as the temperature of the measurement solution increased from 25° C. to 55° C., the charge-transfer resistance R_{ct} gradually decreased. This is because faster electron transfer occurred at higher temperatures.

The charge-transfer resistance R_{ct} sharply increased above 55° C. at which aggregation of the LCST-type polymer begins, and reached its maximum value at 60° C. Herein, the temperature of 60° C. may refer to a temperature at which the polymers were completely aggregated on the surface of the electrode and the actual electrode area was reduced.

As the temperature of the measurement solution further increased from 60° C. to 70° C., the charge-transfer resistance R_{ct} sharply decreased. This is because the polymers aggregated on the surface of the electrode were separated from the surface of the electrode and the actual electrode area was increased.

### Example 2.3: Analysis of Phase Transition Behavior by Varying Thermoresponsive Polymer and Electrolyte Concentration

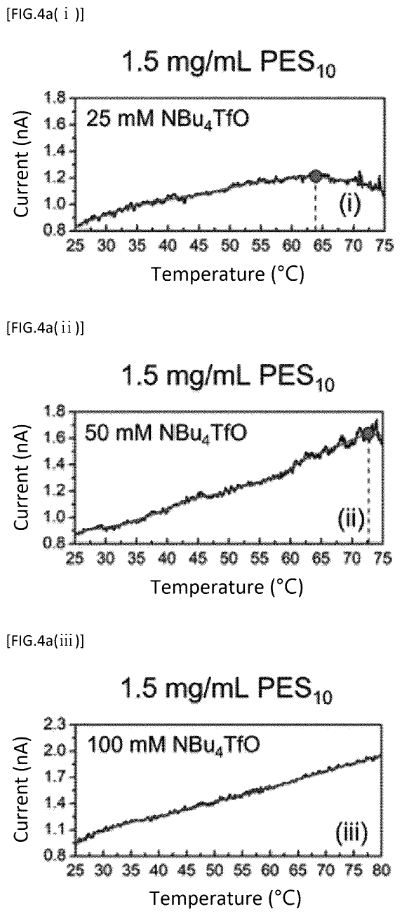

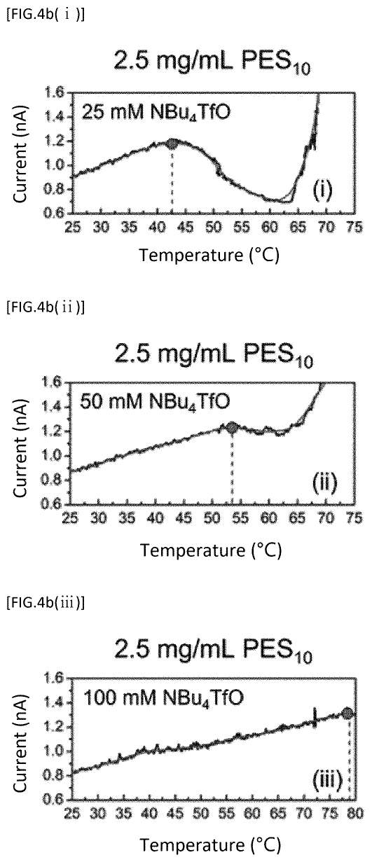

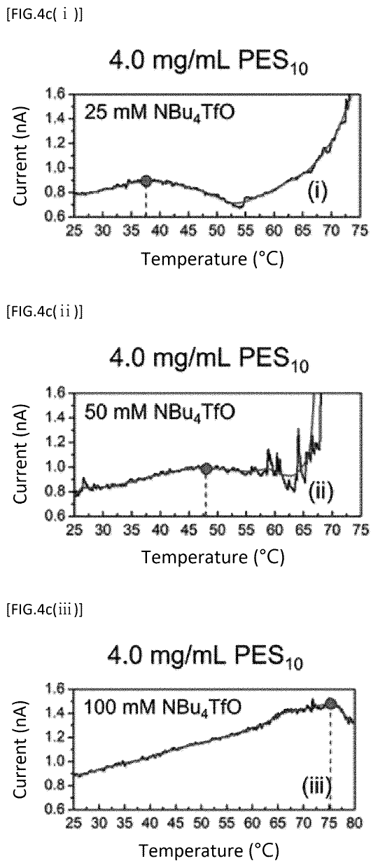

FIG. 4A(i) to FIG. 4A(iii) are graphs of current-temperature (i-T) at different concentrations of the electrolyte (Nbu₄TfO) of 25 mM (i), 50 mM (ii), and 100 mM (iii) when the concentration of the thermoresponsive polymer (PES₁₀) is 1.5 mg/ml. FIG. 4B(i) to FIG. 4B(iii) are graphs of current-temperature (i-T) at different concentrations of the electrolyte (Nbu₄TfO) of 25 mM (i), 50 mM (ii), and 100 mM (iii) when the concentration of the thermoresponsive polymer (PES₁₀) is 2.5 mg/mL. FIG. 4C(i) to FIG. 4C(iii) are graphs of current-temperature (i-T) at different concentrations of the electrolyte (Nbu₄TfO) of 25 mM (i), 50 mM (ii), and 100 mM (iii) when the concentration of the thermoresponsive polymer (PES₁₀) is 4.0 mg/mL.

Referring to FIG. 4A(i) to FIG. 4C(iii), it can be seen that the electrochemical cloud point temperature T_{ecp} of the thermoresponsive polymer is varied depending on the concentration of the thermoresponsive polymer and the concentration of electrolyte.

According to an aspect of the present disclosure, the electrochemical cloud point temperature T_{ecp} tended to decrease as the concentration of the thermoresponsive polymer increased under the same electrolyte concentration conditions.

According to another aspect of the present disclosure, the electrochemical cloud point temperature T_{ecp} tended to increase as the concentration of the electrolyte increased under the same thermoresponsive polymer concentration conditions. This indicates that as the concentration of the electrolyte NBu₄TfO increases, aggregation of LCST-type polymers can be effectively suppressed, which results in an increase in electrochemical cloud point temperature at which aggregation of polymers begins. For example, when the concentration of the electrolyte was 100 mM and the concentration of the thermoresponsive polymer was 1.5 mg/mL, the thermoresponsive polymer was not aggregated. Thus, it can be seen that the electrochemical cloud point temperature was not detected. That is, it can be presumed that when the concentration of the electrolyte is high and the concentration of the thermoresponsive polymer is low, thermoresponsive polymer aggregates are not formed.

### Example 3: Comparison Between Electrochemical Cloud Point Temperature T_{ecp} And Cloud Point Temperature T_{cp}

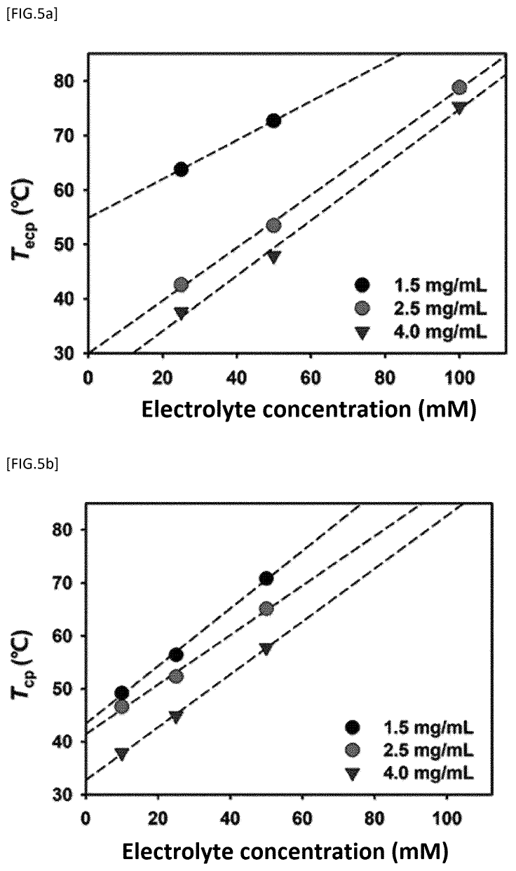

FIG. 5A is a graph of the electrochemical cloud point temperature T_{ecp} depending on the concentration of the electrolyte derived by using the device for thermoamperometry and thermocoulometry according to the present disclosure, and FIG. 5B is a graph of the cloud point temperature T_{cp} depending on the concentration of the electrolyte derived by using a UV-Vis spectrometer.

Referring to FIG. 5A and FIG. 5B, both the electrochemical cloud point temperature T_{ecp} and the cloud point temperature T_{cp} tended to increase as the concentration of the electrolyte increased under the same thermoresponsive polymer concentration conditions.

Also, both the electrochemical cloud point temperature T_{ecp} and the cloud point temperature T_{cp} tended to decrease as the concentration of the thermoresponsive polymer increased under the same electrolyte concentration conditions.

It can be presumed from the test results that the electrochemical cloud point temperature T_{ecp} newly derived by using the device for thermoamperometry and thermocoulometry according to the present disclosure can replace or supplement the conventional cloud point temperature T_{cp}.

### Example 4: Analysis Method Using Device for Thermoamperometry and Thermocoulometry

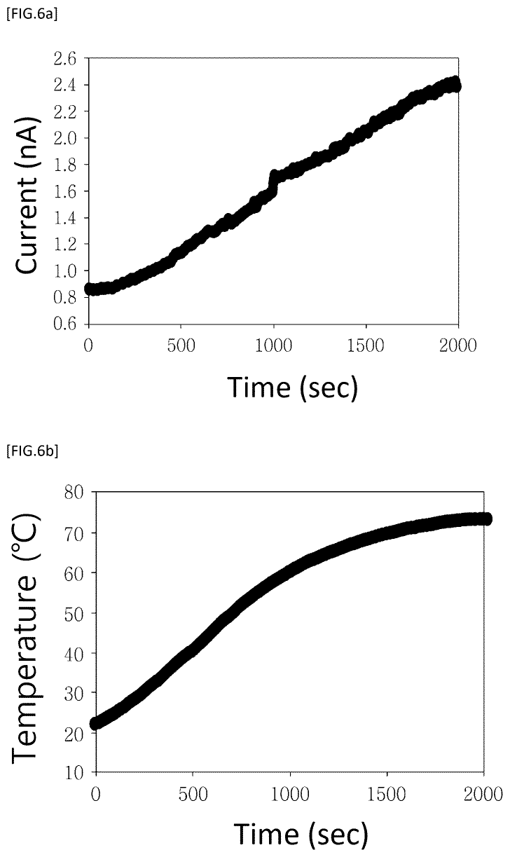

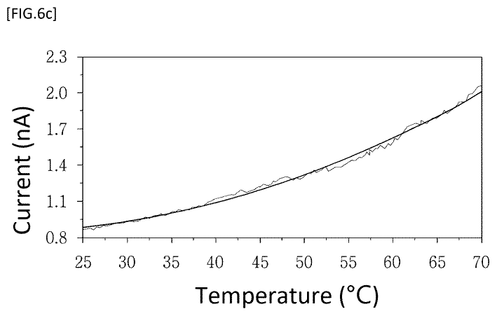

FIG. 6A is a graph of a current (nA) of a measurement solution depending on a time(s) which is output by using the device for thermoamperometry and thermocoulometry according to the present disclosure. FIG. 6B is a graph of a temperature (°C) of the measurement solution depending on the time(s) which is output by using the device for thermoamperometry and thermocoulometry according to the present disclosure. FIG. 6C is a graph of the current (nA) of the measurement solution depending on the temperature (C) of the measurement solution which is output by using the device for thermoamperometry and thermocoulometry according to the present disclosure. Herein, the measurement solution contains polystyrene, which is a non-thermoresponsive polymer, (target material), 0.1 mM anthracene (redox species), and an electrolyte (NBu₄TfO). The temperature of the measurement solution was controlled between 25° C. and 70° C.

Referring to FIG. 6A to FIG. 6C, the device for thermoamperometry and thermocoulometry may be used to implement the analysis method including: a process of outputting first data regarding continuous temperature changes of the measurement solution over time; a process of outputting second data regarding a current of the measurement solution over time; and a process of outputting third data regarding the current of the measurement solution depending on continuous temperature changes of the measurement solution, based on the first and second data. Accordingly, it is possible to easily solve the conventional problem of having to individually plot a current or charge for each specific temperature point to obtain current or charge data of a measurement solution, which results in excessive time and cost consumption.

The embodiments of the present disclosure have been described in detail, but the scope of the present disclosure is not limited thereto. Various modifications and improvements by a person with ordinary skill in the art using the fundamental concept of the present disclosure defined in the accompanying claims are also included in the scope of the present disclosure.

### DESCRIPTION OF THE SYMBOLS

10: chamber

20: electrode unit

20a: counter electrode

20b: reference electrode

20c: working electrode

30: temperature measurement unit

40: temperature controller

50: controller

60: output unit

100: device for thermoamperometry and thermocoulometry

We claim:

1. A device for thermoamperometry and thermocoulometry, comprising:
a chamber filled with a measurement solution containing a target material and an electrolyte;
an electrode unit immersed in the measurement solution;
a temperature controller adjusting a temperature of the measurement solution;
a temperature measurement unit immersed in the measurement solution and spaced apart from the electrode unit; and
a controller connected to both the temperature measurement unit and the electrode unit.

2. The device of claim 1,
wherein the target material includes at least one selected from a conductive material and a non-conductive material.

3. The device of claim 2,
wherein the target material iincludes the non-conductive material and
wherein the measurement solution further includes a redox species.

4. The device of claim 1,
wherein the target material includes a thermoresponsive polymer.

5. The device of claim 4,
wherein the thermoresponsive polymer includes a lower critical solution temperature (LCST) polymer.

6. The device of claim 1,
wherein the electrode unit includes a working electrode and a reference electrode spaced apart from each other.

7. The device of claim 6,
wherein the electrode unit further includes a counter electrode.

8. The device of claim 1, further comprising
an output unit connected to the controller.

9. An analysis method using the device for thermoamperometry and thermocoulometry according to claim 1, comprising:
a process of outputting a first data regarding a temperature of the measurement solution over time;
a process of outputting a second data regarding a current or charge of the measurement solution over time; and
a process of outputting a third data regarding the current or charge of the measurement solution depending on the temperature of the measurement solution, based on the first and second data.
